(19) United States
(12) Patent Application Publication
(10) Pub. No.: US 2025/0174572 A1
(43) Pub. Date: May 29, 2025

(54) SEMICONDUCTOR PACKAGE

(71) Applicant: Samsung Electronics Co., Ltd., Suwon-si (KR)

(72) Inventor: Hyun Ung Han, Suwon-si (KR)

(21) Appl. No.: 18/816,057

(22) Filed: Aug. 27, 2024

(30) Foreign Application Priority Data
Nov. 29, 2023 (KR) 10-2023-0169395

(51) Int. Cl. H01L 23/544; H01L 21/66; H01L 23/00; H01L 23/31; H01L 23/498; H01L 25/18; H10B 80/00

(52) U.S. Cl. CPC H01L 23/544; H01L 22/32; H01L 23/3135; H01L 23/49822; H01L 24/08; H01L 24/95; H01L 24/96; H01L 24/97; H01L 25/18; H01L 24/16; H01L 2223/54426; H01L 2224/08145; H01L 2224/16227; H01L 2224/95136; H01L 2224/97; H01L 2225/06517; H01L 2225/0652; H01L 2225/06541; H01L 2225/06548; H01L 2225/06565; H01L 2225/06593; H01L 2225/06596; H01L 2924/1431; H10B 80/00

(57) ABSTRACT

Provided is a semiconductor package that may improve performance and reliability of a product. The semiconductor package includes a buffer die and a core die on the buffer die. The buffer die may include a first substrate including a scribe lane region and a chip region defined by the scribe lane region, a bump pad in the first substrate, a test pad in the first substrate, and a first alignment key in the first substrate. The core die may include a second substrate on the first substrate, and a second alignment key in the second substrate. The chip region may include a first region having the test pad therein and a second region other than the first region, and the first alignment key may be in the second region.

### CROSS-REFERENCE TO RELATED APPLICATIONS

This application claims priority from Korean Patent Application No. 10-2023-0169395 filed on Nov. 29, 2023 in the Korean Intellectual Property Office and all the benefits accruing therefrom under 35 U.S.C. 119, the contents of which in its entirety are herein incorporated by reference.

### BACKGROUND OF THE INVENTION

The present disclosure relates to a semiconductor package, and more particularly, to a semiconductor package that improves performance and reliability of a product by forming an alignment key so as not to overlap a test pad.

As the electronics industry has developed, the demand for high integration of semiconductor elements has increased. Accordingly, various problems such as a decrease in a process margin of an exposure process for defining fine patterns can occur, making it increasingly difficult to implement a semiconductor element. In addition, with the development of the electronics industry, the demand for high speed of semiconductor elements has also increased. Various studies have been made to meet the demands for high integration and/or high speed of semiconductor elements.

### SUMMARY OF THE INVENTION

An object of the present disclosure is to provide a semiconductor package that may improve performance and reliability of a product.

The objects of the present disclosure are not limited to those mentioned above and additional objects of the present disclosure, which are not mentioned herein, will be understood by those skilled in the art from the following description of the present disclosure.

According to some aspects of the present disclosure, there is provided a semiconductor package comprising a buffer die, and a core die on the buffer die, wherein the buffer die comprises a first substrate including a scribe lane region and a chip region defined by the scribe lane region, the first substrate having first and second surfaces opposite to each other in a first direction, a bump pad in the first substrate and including a lower surface that is coplanar with the first surface of the first substrate, a test pad in the first substrate and including a lower surface that is coplanar with the first surface of the first substrate, and a first alignment key in the first substrate and including an upper surface that is coplanar with the second surface of the first substrate, wherein the core die comprises a second substrate on the second surface of the first substrate, the second substrate including a third surface facing the second surface of the first substrate and a fourth surface opposite to the third surface, and a second alignment key in the second substrate and including an upper surface that is coplanar with the fourth surface of the second substrate, wherein the chip region includes a first region having the test pad therein and a second region other than the first region, and wherein the first alignment key is in the second region.

According to some aspects of the present disclosure, there is provided a semiconductor package comprising a buffer die, and first and second core dies stacked in a first direction on the buffer die, wherein the buffer die comprises a first substrate including first and second surfaces opposite to each other in the first direction, a plurality of bump pads in the first substrate, including respective lower surfaces that are coplanar with the first surface of the first substrate, and configured to electrically connect to an external device, a plurality of test pads in the first substrate, including respective lower surfaces that are coplanar with the first surface of the first substrate, and configured to receive an electrical signal in an electrical die sorting (EDS) process, a first bonding pad on the second surface of the first substrate, and a first alignment key in the first substrate and including an upper surface that is coplanar with the second surface of the first substrate, wherein the first core die comprises a second substrate on the second surface of the first substrate, the second substrate including a third surface facing the second surface of the first substrate and a fourth surface opposite to the third surface, a second alignment key in the second substrate and including an upper surface that is coplanar with the fourth surface of the second substrate, a second bonding pad between the third surface of the second substrate and the second surface of the first substrate, and a third bonding pad on the fourth surface of the second substrate, wherein the second core die comprises a third substrate on the fourth surface of the second substrate, the third substrate including a fifth surface facing the fourth surface of the second substrate and a sixth surface opposite to the fifth surface, a third alignment key in the third substrate and including an upper surface that is coplanar with the sixth surface of the third substrate, and a fourth bonding pad between the fourth surface of the second substrate and the fifth surface of the third substrate, wherein the first bonding pad and the second bonding pad are in contact with each other and electrically connect the buffer die to the first core die, wherein the third bonding pad and the fourth bonding pad are in contact with each other and electrically connect the first core die to the second core die, and wherein the first alignment key does not overlap the plurality of test pads in the first direction.

According to some aspects of the present disclosure, there is provided a semiconductor package comprising a circuit board, an interposer structure on the circuit board, a die structure on the interposer structure and electrically connected to the interposer structure, and a connection terminal between the die structure and the interposer structure, wherein the die structure includes a buffer die and a core die on the buffer die, wherein the buffer die comprises a first substrate including a scribe lane region and a chip region defined by the scribe lane region, the first substrate having first and second surfaces opposite to each other in a first direction, a bump pad in the first substrate, including a lower surface that is coplanar with the first surface of the first substrate, and electrically connected to the connection terminal, a test pad in the first substrate, including a lower surface that is coplanar with the first surface of the first substrate, and configured to receive an electrical signal in an electrical die sorting (EDS) process, a first bonding pad on the second surface of the first substrate, and a first alignment key in the first substrate and including an upper surface that is coplanar with the second surface of the first substrate, wherein the core die comprises a second substrate on the second surface of the first substrate, the second substrate including a third surface facing the second surface of the first substrate and a fourth surface opposite to the third surface, a second bonding pad between the third surface of the second substrate and the second surface of the first substrate, and a second alignment key in the second substrate, including an upper surface that is coplanar with the fourth surface of the second substrate, and aligned with the first alignment key in the first direction, wherein the first bonding pad and the second bonding pad are in contact with each other and electrically connect the buffer die to the core die, wherein the chip region includes a first region having the test pad therein and a second region other than the first region, and wherein the first alignment key is in the second region.

### BRIEF DESCRIPTION OF THE DRAWINGS

FIG. 1 is an example plan view illustrating a semiconductor package according to some embodiments of the present disclosure.

FIG. 2 is an example cross-sectional view taken along line A-A of FIG. 1.

FIG. 3 is an enlarged view illustrating a region P of FIG. 2.

FIGS. 4a, 4b, and 4c are example plan views illustrating an alignment key of FIG. 1.

FIGS. 5 and 6 are example views illustrating a semiconductor package according to some other embodiments of the present disclosure.

FIGS. 7 and 8 are example views illustrating a semiconductor package according to some other embodiments of the present disclosure.

FIGS. 9 and 10 are example views illustrating a semiconductor package according to some other embodiments of the present disclosure.

FIGS. 11 to 21 are intermediate views illustrating a method of manufacturing a semiconductor package according to some embodiments of the present disclosure.

### DETAILED DESCRIPTION

It will be understood that, although the terms “first”, “second”, “upper portion”, “lower portion”, “upper surface”, “lower surface”, etc. may be used herein to describe various elements or components, these elements or components should not be limited by these terms. Rather, these terms are only used to distinguish one element or component from another element or component. Therefore, a first element or component discussed below could also be termed a second element or component without departing from the scope of the present disclosure.

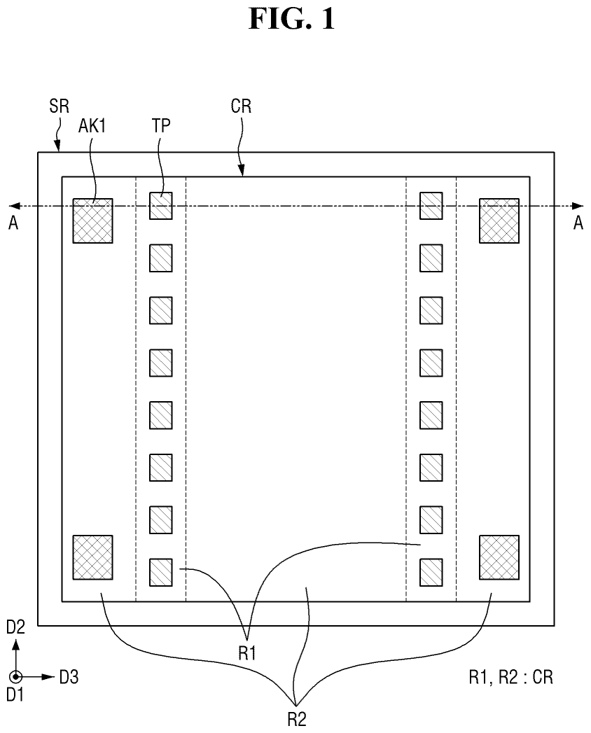

Hereinafter, a semiconductor package according to example embodiments will be described with reference to FIGS. 1 to 10.

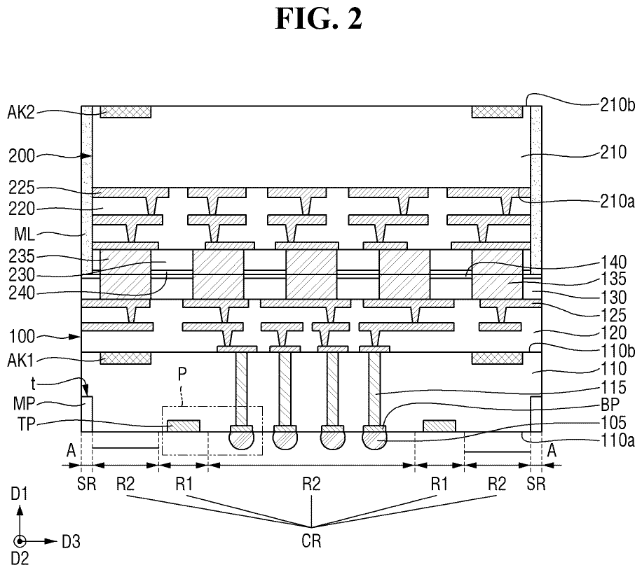

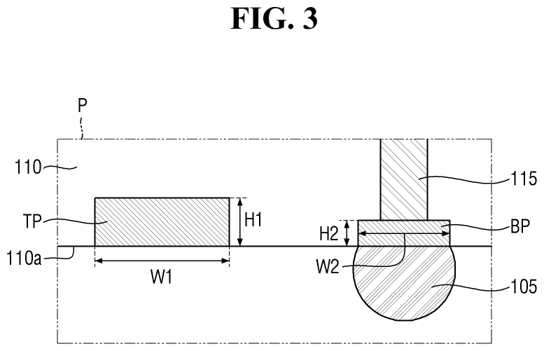

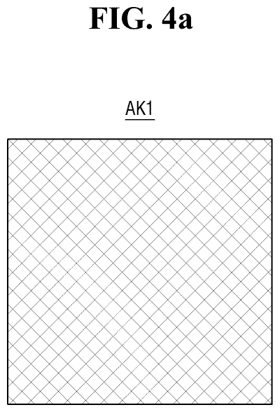

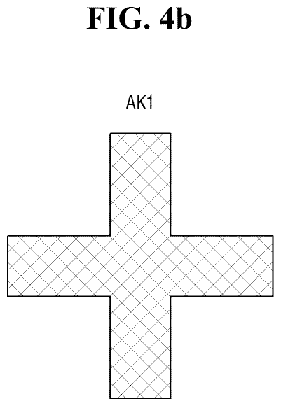

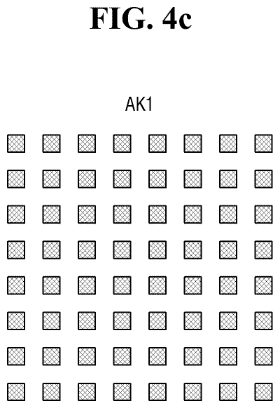

First, a semiconductor package according to some embodiments of the present disclosure will be described with reference to FIGS. 1 to 4c. FIG. 1 is an example plan view illustrating a semiconductor package according to some embodiments of the present disclosure. FIG. 2 is an example cross-sectional view taken along line A-A of FIG. 1. FIG. 3 is an enlarged view illustrating a region P of FIG. 2. FIGS. 4a, 4b, and 4c are example plan views illustrating an alignment key of FIG. 1.

Referring to FIGS. 1 to 4c, a semiconductor package according to some embodiments may include a buffer die 100, a core die 200, and first connection terminals 105.

The buffer die 100 and the core die 200 may constitute a die structure. Although FIG. 2 shows that one core die 200 is disposed on the buffer die 100, the present disclosure is not limited thereto. In some embodiments, two or more core dies 200 may be disposed on the buffer die 100, and in this case, one buffer die 100 and two or more core dies 200 may constitute the die structure.

The core die 200 may be disposed on the buffer die 100. The buffer die 100 and the core die 200 may be aligned in a first direction D1. The buffer die 100 may be also referred to as an interface die, a base die, a logic die, a master die, or the like. The core die 200 may be also referred to as a memory die, a slave die, or the like.

In some embodiments, the buffer die 100 may include a physical layer and a direct access region. The physical layer of the buffer die 100 may include interface circuits for communication with an external host device, and the external host device may be electrically connected to the buffer die 100 through the first connection terminal 105 that will be described in greater detail below.

The core die 200 may receive signals from the buffer die 100 or transmit the signals to the buffer die 100 through the physical layer. Signals and/or data received through the physical layer of the buffer die 100 may be transferred to the core die 200 through bonding pads 135 and 235. The direct access region may provide an access path capable of testing the core die 200 without passing through the buffer die 100. The direct access region may include a conductive means capable of directly performing communication with an external test device. In some embodiments, the core die 200 may include a memory cell array, but present disclosure is not limited thereto.

In some embodiments, the buffer die 100 may include a first substrate 110, test pads TP, bump pads BP, and first alignment keys AK1.

The first substrate 110 may be, for example, bulk silicon or a silicon-on-insulator (SOI). As another example, the first substrate 110 may be a silicon substrate, or may include another material, for example, silicon germanium, silicon germanium on insulator (SGOI), indium antimony, lead telluride compound, indium arsenic, indium phosphide, gallium arsenic, or gallium antimony, but is not limited thereto.

In some embodiments, the first substrate 110 may include a first surface 110a and a second surface 110b, which are opposite to each other in the first direction D1. The first surface 110a may be opposite to the core die 200. The second surface 110b may face the core die 200. The first connection terminal 105 may be disposed on the first surface 110a. The core die 200 and the first bonding pad 135 may be disposed on the second surface 110b.

In some embodiments, the first substrate 110 may include a scribe lane region SR and a chip region CR. The scribe lane region SR may define the chip region CR. That is, the chip region CR may be surrounded by the scribe lane region SR. The core die 200 may be disposed on the chip region CR, but the present disclosure is not limited thereto. It will be understood that “an element A surrounds an element B” (or similar language) as used herein means that the element A is at least partially around the element B but does not necessarily mean that the element A completely encloses the element B.

In some embodiments, the first substrate 110 may include a trench ‘t’ on the scribe lane region SR. The trench ‘t’ may extend from the first surface 110a toward the second surface 110b. The trench ‘t’ may not pass through the first substrate 110. That is, a depth of the trench ‘t’ in the first direction D1 may be less than a thickness of the first substrate 110 in the first direction D1. In the trench ‘t’, a metal pattern MP may be disposed. The scribe lane region SR may be defined by the metal pattern MP. The metal pattern MP may include a metal material, but the present disclosure is not limited thereto.

In some embodiments, the chip region CR may include a first region R1 and a second region R2. The first region R1 may be a region in which the test pad TP is disposed. That is, the first region R1 may have the test pad TP therein. The second region R2 may be a region other than the first region R1.

The first region R1 may extend longitudinally in a second direction D2. The first region R1 may include a pair of sub-regions that extend longitudinally in the second direction D2 and are spaced apart from each other in a third direction D3. The test pads TP may be arranged in series in the second direction D2 on the pair of sub-regions, but the present disclosure is not limited thereto. For example, the first direction D1 may be perpendicular to the first surface 110a of the first substrate 110, and each of the second and third directions D2 and D3 may be parallel to the first surface 110a of the first substrate 110. The first, second, and third directions D1, D2, and D3 may intersect each other.

The second region R2 may be provided in a space between the scribe lane region SR and the first region R1 and between the pair of sub-regions. That is, in FIG. 1, the second region R2 may be divided into three portions by the first region R1. The second region R2 may be a region in which the first alignment key AK1 and the bump pad BP are disposed. For example, the first alignment key AK1 may be interposed between the scribe lane region SR and the first region R1. For example, the first alignment key AK1 may not be between the pair of sub-regions of the first region R1, and the first alignment key AK1 may be between one of the pair of sub-regions of the first region R1 and the scribe lane region SR. The bump pad BP may be interposed in a space between the pair of sub-regions of the first region R1.

The test pad TP may be disposed inside the first substrate 110 in the first region R1. The test pad TP may expose the first surface 110a of the first substrate 110. That is, in FIG. 2, a lower surface of the test pad TP may be disposed on the same plane as (i.e., may be coplanar with) the first surface 110a. The lower surface of the test pad TP may be opposite to the core die 200.

The test pad TP may be used to perform an electrical die sorting (EDS) test process. In other words, the test pad TP may facilitate the EDS test process. The EDS test process is a process of testing whether an individual chip or an individual die is electrically operated. That is, through the EDS test process, whether the buffer die 100 and the core die 200 are electrically operated may be tested. The test pad TP may be in contact with a probe needle in the EDS test process. The EDS test process may be performed using a probe card or the like. For example, the EDS test process may be performed as the probe needle, which is a terminal pin included in the probe card, is in contact with the test pad TP and an electrical signal is applied. For example, the test pad TP may receive the electrical signal in the EDS test process.

The bump pad BP may be disposed inside the first substrate 110 in the second region R2. The bump pad BP may expose the first surface 110a of the first substrate 110. That is, in FIG. 2, a lower surface of the bump pad BP may be disposed on the same plane as (i.e., may be coplanar with) the first surface 110a. The lower surface of the bump pad BP may be opposite to the core die 200.

The bump pad BP may be used to electrically connect an external device to the buffer die 100. The first connection terminal 105 may be disposed below the bump pad BP. For example, the first connection terminal 105 may be connected to the bump pad BP. Although not shown, the first connection terminal 105 and the external device may be electrically connected to each other, and the external device and the buffer die 100 may be electrically connected to each other through the first connection terminal 105. As used herein, “an element A connected to an element B” (or similar language) means that the element A is physically and/or electrically connected to the element B.

The first connection terminal 105 may be formed of a single layer or a multi-layer. When the first connection terminal 105 is formed of a single layer, the first connection terminal 105 may include, for example, a tin-silver (Sn—Ag) solder or copper (Cu). When the first connection terminal 105 is formed of a multi-layer, the first connection terminal 105 may include, for example, a copper (Cu) filler and a solder, but the present disclosure is not limited thereto. The number, interval, arrangement, shape and the like of the first connection terminals 105 are not limited to the shown examples, and may vary depending on design.

In FIG. 3, a size of the test pad TP may be greater than that of the bump pad BP. For example, a height H1 of the test pad TP is higher than a height H2 of the bump pad BP in the first direction D1. That is, a thickness of the test pad TP in the first direction D1 is greater than that of the bump pad BP in the first direction D1. Also, a width W1 of the test pad TP is greater than a width W2 of the bump pad BP in the third direction D3. That is, a thickness of the test pad TP in the third direction D3 is greater than that of the bump pad BP in the third direction D3, but the present disclosure is not limited thereto. As used herein, “a size of the test pad” may refer to the height Hl and/or the width W1 of the test pad TP. Similarly, as used herein, “a size of the bump pad” may refer to the height H2 and/or the width W2 of the bump pad BP. Each of the test pad TP and the bump pad BP may include, for example, a metal material such as copper (Cu) or aluminum (Al), but is not limited thereto.

In FIG. 2 again, the first alignment key AK1 may be disposed inside the first substrate 110 in the second region R2. The first alignment key AK1 may expose the second surface 110b of the first substrate 110. That is, in FIG. 2, an upper surface of the first alignment key AK1 may be disposed on the same plane as (i.e., may be coplanar with) the second surface 110b. The upper surface of the first alignment key AK1 may face the core die 200.

The first alignment key AK1 may be used to align the buffer die 100 and the core die 200 in the first direction D1. For example, the core die 200 includes second alignment keys AK2. The first alignment key AK1 and the second alignment key AK2 may overlap each other in the first direction D1 so that the buffer die 100 and the core die 200 may be aligned in the first direction D1. As used herein, “an element A overlaps an element B in a direction X” (or similar language) means that there is at least one straight line that extends in the direction X and intersects both the elements A and B.

The first alignment key AK1 and the second alignment key AK2 may be aligned in the first direction D1. As used herein, “the first alignment key AK1 and the second alignment key AK2 are aligned in the first direction D1” may mean that the first alignment key AK1 and the second alignment key AK2 completely overlap each other in the first direction D1. Also, as used herein, “the first alignment key AK1 and the second alignment key AK2 are aligned in the first direction D1” may mean that the center of the first alignment key AK1 and the center of the second alignment key AK2 are aligned in the first direction D1.

In FIGS. 4a to 4c, the first alignment key AK1 may have various shapes. For example, when viewed in a plan view, the first alignment key AK1 may have a rectangular shape and/or a cross shape (see FIGS. 4a and 4b). In addition, the first alignment key AK1 may have a shape in which a plurality of small rectangles are disposed (see FIG. 4c).

In some embodiments, the shapes of the first alignment key AK1 and the second alignment key AK2 may be the same as each other, but the present disclosure is not limited thereto. In some other embodiments, the shapes of the first alignment key AK1 and the second alignment key AK2 may be different from each other.

In some embodiments, the first alignment key AK1 is disposed in the second region R2, and the test pad TP is disposed in the first region R1. That is, the first alignment key AK1 and the test pad TP do not completely overlap each other in the first direction D1. For example, the first alignment key AK1 and the test pad TP may not overlap each other in the first direction D1 or may only partially overlap each other in the first direction D1. For example, the test pad TP may be spaced apart from the first alignment key AK1 in the third direction D3. As the semiconductor package has the above structure, the first alignment key AK1 and the second alignment key AK2 may be effectively recognized even though the semiconductor package is miniaturized. Therefore, a semiconductor package with improved performance and reliability may be provided.

In some embodiments, the buffer die 100 may further include first through vias 115, a first insulating layer 120, a first redistribution layer 125, a first passivation layer 130, and first bonding pads 135.

The first through via 115 may be disposed in the first substrate 110. The first through via 115 may extend from the second surface 110b of the first substrate 110 in the first direction D1. The first through via 115 may serve to electrically connect the first redistribution layer 125 with the bump pad BP. That is, the first redistribution layer 125 and the bump pad BP may be electrically connected to each other through the first through via 115. The first through via 115 may include, for example, a metal material such as copper (Cu) or aluminum (Al), but is not limited thereto.

The first insulating layer 120 may be disposed on the second surface 110b of the first substrate 110. The first insulating layer 120 may be made of a photoimageable dielectric (PID). For example, the first insulating layer 120 may include a photosensitive polymer. The photosensitive polymer may be formed of at least one of, for example, a photosensitive polyimide, polybenzoxazole, a phenol-based polymer or a benzocyclobutene-based polymer. For another example, the first insulating layer 120 may be formed of a silicon oxide film, a silicon nitride film, or a silicon oxynitride film.

The first redistribution layer 125 may be disposed in the first insulating layer 120. The first redistribution layer 125 may include a plurality of layers (which may also be referred to as a plurality of redistribution patterns). For example, the first redistribution layer 125 may include a wiring portion extending in the third direction D3 and a via portion connected to the wiring portion and extending in the first direction D1. Also, the first redistribution layer 125 may include a first sub-layer and a second sub-layer, and the via portion of the first sub-layer may be connected to the wiring portion of the second sub-layer. For example, at least a portion of the first redistribution layer 125 may overlap the first alignment key AK1 in the first direction D1.

In this case, a level of the wiring portion of the first sub-layer may be different from a level of the wiring portion of the second sub-layer in the first direction D1, but the present disclosure is not limited thereto.

The first redistribution layer 125 disposed at the lowest level in the first direction D1 may be connected to the first through via 115. The first redistribution layer 125 disposed at the highest level in the first direction D1 may be connected to the first bonding pad 135. The first redistribution layer 125 may include, for example, copper (Cu), aluminum (Al), silver (Ag), tin (Sn), gold (Au), nickel (Ni), lead (Pb), titanium (Ti) or their alloys, but is not limited thereto.

The first passivation layer 130 is disposed on the first insulating layer 120. The first passivation layer 130 may include an insulating material. For example, the first passivation layer 130 may be formed of a silicon oxide film.

A first bonding insulating film 140 may be disposed on the first passivation layer 130. The first bonding insulating film 140 may extend longitudinally along an upper surface of the first passivation layer 130. The first bonding insulating film 140 may include an insulating material different from that of the first passivation layer 130. For example, the first bonding insulating film 140 may be formed of a silicon carbonitride film (SiCN).

The first bonding pad 135 may be disposed in the first passivation layer 130. The first bonding pad 135 may pass through the first bonding insulating film 140 and the first passivation layer 130. That is, a lower surface of the first bonding pad 135 may be coplanar with that of the first passivation layer 130, and an upper surface of the first bonding pad 135 may be coplanar with that of the first bonding insulating film 140. The first bonding pad 135 may be used to electrically connect the buffer die 100 with the core die 200.

For example, the core die 200 may include second bonding pads 235, and as the second bonding pad 235 is bonded to the first bonding pad 135, the buffer die 100 and the core die 200 may be electrically connected to each other. The first bonding pad 135 may include a conductive metal material. For example, the first bonding pad 135 may be formed of copper (Cu), but is not limited thereto.

In some embodiments, the core die 200 may include a second substrate 210, second alignment keys AK2, a second insulating layer 220, a second redistribution layer 225, a second passivation layer 230, second bonding pads 235, and a second bonding insulating film 240.

The second substrate 210 may be, for example, bulk silicon or a silicon-on-insulator (SOI). As another example, the second substrate 210 may be a silicon substrate, or may include another material, for example, silicon germanium, silicon germanium on insulator (SGOI), indium antimony, lead telluride compound, indium arsenic, indium phosphide, gallium arsenic, or gallium antimony, but is not limited thereto.

In some embodiments, the second substrate 210 may include a third surface 210a and a fourth surface 210b, which are opposite to each other in the first direction D1. The third surface 210a may face the buffer die 100. The fourth surface 210b may be opposite to the buffer die 100. That is, the buffer die 100 and the second bonding pad 235 may be disposed on the third surface 210a.

The second alignment key AK2 may be disposed inside the second substrate 210 in the second region R2. The second alignment key AK2 may expose the fourth surface 210b of the second substrate 210. That is, in FIG. 2, an upper surface of the second alignment key AK2 may be disposed on the same plane as (i.e., may be coplanar with) the fourth surface 210b. The upper surface of the second alignment key AK2 may be opposite to the buffer die 100.

As described above, the second alignment key AK2 may be used to align the buffer die 100 with the core die 200. The first alignment key AK1 and the second alignment key AK2 may overlap each other in the first direction D1 so that the buffer die 100 and the core die 200 may be aligned in the first direction D1.

The second insulating layer 220 may be disposed on the third surface 210a of the second substrate 210. That is, the second insulating layer 220 may be interposed between the second substrate 210 and the first substrate 110. The second insulating layer 220 may be disposed below the second substrate 210. The second insulating layer 220 may be made of a photoimageable dielectric (PID). For example, the second insulating layer 220 may include a photosensitive polymer. The photosensitive polymer may be formed of at least one of, for example, a photosensitive polyimide, polybenzoxazole, a phenol-based polymer or a benzocyclobutene-based polymer. For another example, the second insulating layer 220 may be formed of a silicon oxide film, a silicon nitride film, or a silicon oxynitride film.

The second redistribution layer 225 may be disposed in the second insulating layer 220. The second redistribution layer 225 may include a plurality of layers (which may also be referred to as a plurality of redistribution patterns). For example, the second redistribution layer 225 may include a wiring portion extending in the third direction D3 and a via portion connected to the wiring portion and extending in the first direction D1.

For example, the second redistribution layer 225 may include a first sub-layer and a second sub-layer, and the via portion of the first sub-layer may be connected to the wiring portion of the second sub-layer. In this case, a level of the wiring portion of the first sub-layer may be different from a level of the wiring portion of the second sub-layer in the first direction D1, but the present disclosure is not limited thereto.

The second redistribution layer 225 disposed at the lowest level in the first direction D1 may be connected to the second bonding pad 235. The second redistribution layer 225 disposed at the highest level in the first direction D1 may be connected to a chip pad or circuit elements in the second substrate 210. The second redistribution layer 225 may include, for example, copper (Cu), aluminum (Al), silver (Ag), tin (Sn), gold (Au), nickel (Ni), lead (Pb), titanium (Ti) or their alloys, but is not limited thereto.

The second passivation layer 230 is disposed below the second insulating layer 220. For example, the second passivation layer 230 may be interposed between the second insulating layer 220 and the buffer die 100. The second passivation layer 230 may include an insulating material. For example, the second passivation layer 230 may be formed of a silicon oxide film.

The second bonding insulating film 240 may be disposed below the second passivation layer 230. The second bonding insulating film 240 may extend longitudinally along a lower surface of the second passivation layer 230. The second bonding insulating film 240 may include an insulating material different from that of the second passivation layer 230. For example, the second bonding insulating film 240 may be formed of a silicon carbonitride film (SiCN).

The second bonding pad 235 may be disposed in the second passivation layer 230. The second bonding pad 235 may pass through the second bonding insulating film 240 and the second passivation layer 230. That is, an upper surface of the second bonding pad 235 may be coplanar with that of the second passivation layer 230, and a lower surface of the second bonding pad 235 may be coplanar with that of the second bonding insulating film 240. The second bonding pad 235 may be used to electrically connect the buffer die 100 to the core die 200.

For example, as the second bonding pad 235 is bonded to the first bonding pad 135, the buffer die 100 and the core die 200 may be electrically connected to each other. The second bonding pad 235 may include a conductive metal material. For example, the second bonding pad 235 may be formed of copper (Cu), but is not limited thereto.

The semiconductor package according to some embodiments may further include a mold layer ML. The mold layer ML may be disposed on sidewalls of the core die 200. The mold layer ML may not be disposed on sidewalls of the buffer die 100, but the present disclosure is not limited thereto. The mold layer ML may include, for example, an insulating polymer material such as an epoxy molding compound (EMC), but is not limited thereto. The first alignment key AK1 may not completely overlap the mold layer ML in the first direction D1. For example, the first alignment key AK1 may not overlap the mold layer ML in the first direction D1 or may only partially overlap the mold layer ML in the first direction D1. For example, the first alignment key AK1 may be spaced apart from the mold layer ML in the third direction D3.

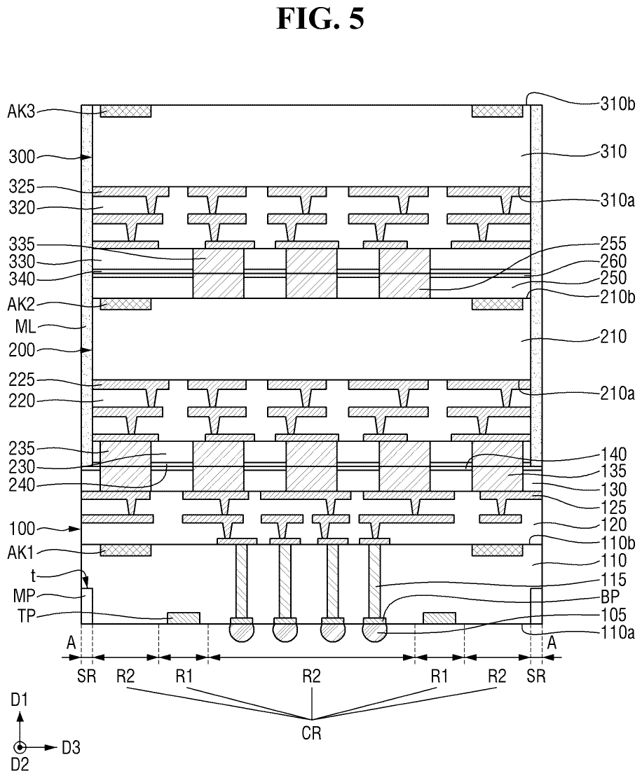

Hereinafter, a semiconductor package according to some other embodiments of the present disclosure will be described with reference to FIGS. 5 to 10. For convenience of explanation, a redundant description of that made with reference to FIGS. 1 to 4c will be briefly described or omitted.

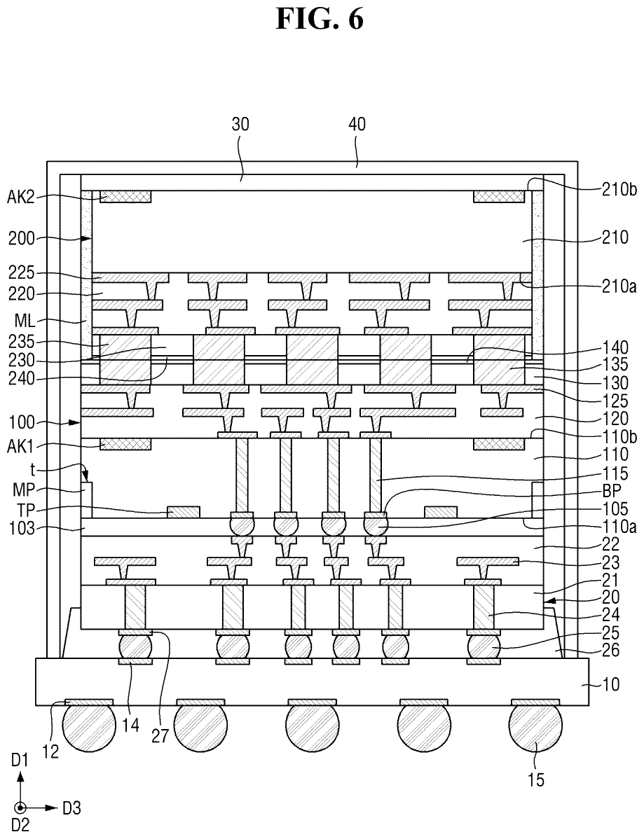

FIGS. 5 and 6 are example views illustrating a semiconductor package according to some other embodiments of the present disclosure.

Referring to FIG. 5, the semiconductor package according to some embodiments of the present disclosure may include one buffer die 100 and a plurality of core dies 200 and 300. For example, the semiconductor package according to some embodiments of the present disclosure may include a buffer die 100, a first core die 200, and a second core die 300. That is, the buffer die 100 and the first and second core dies 200 and 300 may constitute the die structure. A mold layer ML may be on sidewalls of the first and second core dies 200 and 300.

The buffer die 100 may be substantially the same as the buffer die described with reference to FIGS. 1 to 4c, and the first core die 200 may be substantially the same as the core die described with reference to FIGS. 1 to 4c.

In some embodiments, the first core die 200 may further include a third passivation layer 250, third bonding pads 255, and a third bonding insulating film 260.

The third passivation layer 250 is disposed on the second substrate 210. The third passivation layer 250 may be disposed on the fourth surface 210b of the second substrate 210. The third passivation layer 250 may include an insulating material. For example, the third passivation layer 250 may be formed of a silicon oxide film.

The third bonding insulating film 260 may be disposed on the third passivation layer 250. The third bonding insulating film 260 may extend longitudinally along an upper surface of the third passivation layer 250. The third bonding insulating film 260 may include an insulating material different from that of the third passivation layer 250. For example, the third bonding insulating film 260 may be formed of a silicon carbonitride film (SiCN).

The third bonding pad 255 may be disposed in the third passivation layer 250. The third bonding pad 255 may pass through the third bonding insulating film 260 and the third passivation layer 250. That is, a lower surface of the third bonding pad 255 may be coplanar with that of the third passivation layer 250, and an upper surface of the third bonding pad 255 may be coplanar with that of the third bonding insulating film 260. The third bonding pad 255 may be used to electrically connect the first core die 200 with the second core die 300.

For example, the second core die 300 may include fourth bonding pads 335, and as the third bonding pad 255 is bonded to the fourth bonding pad 335, the first core die 200 and the second core die 300 may be electrically connected to each other. The third bonding pad 255 may include a conductive metal material. For example, the third bonding pad 255 may be formed of copper (Cu), but is not limited thereto.

The second core die 300 may include a third substrate 310, third alignment keys AK3, a third insulating layer 320, a third redistribution layer 325, a fourth passivation layer 330, fourth bonding pads 335, and a fourth bonding insulating film 340.

The third substrate 310 may be, for example, bulk silicon or a silicon-on-insulator (SOI). As another example, the third substrate 310 may be a silicon substrate, or may include another material, for example, silicon germanium, silicon germanium on insulator (SGOI), indium antimony, lead telluride compound, indium arsenic, indium phosphide, gallium arsenic, or gallium antimony, but is not limited thereto.

In some embodiments, the third substrate 310 may include a fifth surface 310a and a sixth surface 310b, which are opposite to each other in the first direction D1. The fifth surface 310a may face the first core die 200. The sixth surface 310b may be opposite to the first core die 200. That is, the first core die 200 and the fourth bonding pad 335 may be disposed on the fifth surface 310a.

The third alignment key AK3 may be disposed inside the third substrate 310 in the second region R2. The third alignment key AK3 may expose the sixth surface 310b of the third substrate 310. That is, in FIG. 5, an upper surface of the third alignment key AK3 may be disposed on the same plane as (i.e., may be coplanar with) the sixth surface 310b. The upper surface of the third alignment key AK3 may be opposite to the first core die 200.

The third alignment key AK3 may be used to align the first core die 200 and the second core die 300. In addition, the third alignment key AK3 may be used to align the buffer die 100 and the second core die 300. The second alignment key AK2 and the third alignment key AK3 may overlap each other in the first direction D1 so that the first core die 200 and the second core die 300 may be aligned in the first direction D1. The first alignment key AK1 and the third alignment key AK3 may overlap each other in the first direction D1 so that the buffer die 100 and the second core die 300 may be aligned in the first direction D1. For example, the first alignment key AK1, the second alignment key AK2 and the third alignment key AK3 may be aligned with one another in the first direction D1.

The third insulating layer 320 may be disposed on the fifth surface 310a of the third substrate 310. That is, the third insulating layer 320 may be interposed between the third substrate 310 and the second substrate 210. The third insulating layer 320 may be disposed below the third substrate 310. The third insulating layer 320 may be made of a photoimageable dielectric (PID). For example, the third insulating layer 320 may include a photosensitive polymer. The photosensitive polymer may be formed of at least one of, for example, a photosensitive polyimide, polybenzoxazole, a phenol-based polymer or a benzocyclobutene-based polymer. For another example, the third insulating layer 320 may be formed of a silicon oxide film, a silicon nitride film, or a silicon oxynitride film.

The third redistribution layer 325 may be disposed in the third insulating layer 320. The third redistribution layer 325 may include a plurality of layers (which may also be referred to as a plurality of redistribution patterns). For example, the third redistribution layer 325 may include a wiring portion extending in the third direction D3 and a via portion connected to the wiring portion and extending in the first direction D1.

For example, the third redistribution layer 325 may include a first sub-layer and a second sub-layer, and the via portion of the first sub-layer may be connected to the wiring portion of the second sub-layer. In this case, a level of the wiring portion of the first sub-layer may be different from a level of the wiring portion of the second sub-layer in the first direction D1, but the present disclosure is not limited thereto.

The third redistribution layer 325 disposed at the lowest level in the first direction D1 may be connected to the fourth bonding pad 335. The third redistribution layer 325 disposed at the highest level in the first direction D1 may be connected to a chip pad or circuit elements in the third substrate 310. The third redistribution layer 325 may include, for example, copper (Cu), aluminum (Al), silver (Ag), tin (Sn), gold (Au), nickel (Ni), lead (Pb), titanium (Ti) or their alloys, but is not limited thereto.

The fourth passivation layer 330 is disposed below the third insulating layer 320. For example, the fourth passivation layer 330 may be interposed between the third insulating layer 320 and the first core die 200. The fourth passivation layer 330 may include an insulating material. For example, the fourth passivation layer 330 may be formed of a silicon oxide film.

The fourth bonding insulating film 340 may be disposed below the fourth passivation layer 330. The fourth bonding insulating film 340 may extend longitudinally along a lower surface of the fourth passivation layer 330. The fourth bonding insulating film 340 may include an insulating material different from that of the fourth passivation layer 330. For example, the fourth bonding insulating film 340 may be formed of a silicon carbonitride film (SiCN).

The fourth bonding pad 335 may be disposed in the fourth passivation layer 330. The fourth bonding pad 335 may pass through the fourth bonding insulating film 340 and the fourth passivation layer 330. That is, an upper surface of the fourth bonding pad 335 may be coplanar with that of the fourth passivation layer 330, and a lower surface of the fourth bonding pad 335 may be coplanar with that of the fourth bonding insulating film 340. The fourth bonding pad 335 may be used to electrically connect the first core die 200 with the second core die 300.

For example, as the fourth bonding pad 335 is bonded to the third bonding pad 255, the first core die 200 and the second core die 300 may be electrically connected to each other. The fourth bonding pad 335 may include a conductive metal material. For example, the fourth bonding pad 335 may be formed of copper (Cu), but is not limited thereto.

Referring to FIG. 6, the semiconductor package according to some embodiments may further include a circuit board 10 and an interposer structure 20.

The circuit board 10 may be a package board. The circuit board 10 may be a printed circuit board (PCB). The circuit board 10 may include lower and upper surfaces opposite to each other. The upper surface of the circuit board 10 may face the interposer structure 20. For example, the circuit board 10 may be on the first surface 110a of the first substrate 110 below the buffer die 100.

First board pads 12 and second board pads 14 may be disposed in the circuit board 10. Each of the first board pad 12 and the second board pad 14 may be used to electrically connect the circuit board 10 to other components. For example, the first board pad 12 may be exposed from the lower surface of the circuit board 10, and the second board pad 14 may be exposed from the upper surface of the circuit board 10. For example, a lower surface of the first board pad 12 may be coplanar with the lower surface of the circuit board 10, and an upper surface of the second board pad 14 may be coplanar with the upper surface of the circuit board 10. The first board pad 12 and the second board pad 14 may include, for example, a metal material such as copper (Cu) or aluminum (Al), but are not limited thereto.

Wiring patterns for electrically connecting the first board pad 12 with the second board pad 14 may be formed in the circuit board 10.

The circuit board 10 may be packaged on a main board of an electronic device or the like. For example, second connection terminals 15 connected to the first board pads 12 may be provided. The circuit board 10 may be packaged on the main board of the electronic device or the like through the second connection terminal 15. The circuit board 10 may be a ball grid array (BGA) board, but is not limited thereto.

The second connection terminal 15 may be, for example, a solder bump, but is not limited thereto. The second connection terminal 15 may have various shapes such as a land, a ball, a pin and a pillar. The number, interval, arrangement, shape and the like of the second connection terminals 15 are not limited to the shown examples, and may vary depending on design.

In some embodiments, the circuit board 10 may include a copper clad laminate (CCL). For example, the circuit board 10 may have a structure in which copper laminates are stacked on one side or both sides of a thermosetting prepreg (for example, prepreg of C-Stage).

The interposer structure 20 may be disposed on the upper surface of the circuit board 10. The interposer structure 20 may include a lower surface and an upper surface, which are opposite to each other. The upper surface of the interposer structure 20 may face the buffer die 100 and the core die 200. The lower surface of the interposer structure 20 may face the circuit board 10. The interposer structure 20 may facilitate connection among the circuit board 10, the buffer die 100 and the core die 200, and may prevent warpage of the semiconductor package from occurring.

The interposer structure 20 may be disposed on the circuit board 10. The interposer structure 20 may include an interposer 21, an interlayer insulating layer 22, an interposer redistribution layer 23, second through vias 24, and interposer pads 27.

The interposer 21 may be provided on the circuit board 10. The interposer 21 may be, for example, a silicon (Si) interposer, but is not limited thereto. The interlayer insulating layer 22 may be disposed on the interposer 21. The interlayer insulating layer 22 may include an insulating material. For example, the interlayer insulating layer 22 may include at least one of silicon oxide, silicon nitride, silicon oxynitride or a low dielectric constant (low-k) material having a dielectric constant lower than that of silicon oxide, but is not limited thereto.

The interposer pad 27 may be used to electrically connect the interposer structure 20 to other components. For example, the interposer pad 27 may be exposed from the lower surface of the interposer structure 20. For example, the interposer pad 27 may be on a lower surface of the interposer 21. The interposer pad 27 may include, for example, a metal material such as copper (Cu) or aluminum (Al), but is not limited thereto. Wiring patterns electrically connected to the interposer pad 27 may be formed in the interposer structure 20.

For example, the interposer redistribution layer 23 and the second through via 24 may be formed in the interposer structure 20. The interposer redistribution layer 23 may be disposed in the interlayer insulating layer 22. The second through via 24 may pass through the interposer 21. As a result, the interposer redistribution layer 23 and the second through via 24 may be connected to each other. The second through via 24 may be electrically connected to the interposer pad 27 and the interposer redistribution layer 23. Therefore, the interposer structure 20 and the buffer die 100 may be electrically connected to each other. Each of the interposer redistribution layer 23 and the second through via 24 may include a metal material such as copper (Cu) or aluminum (Al), but is not limited thereto.

The interposer structure 20 may be packaged on the upper surface of the circuit board 10. For example, third connection terminals 25 may be formed between the circuit board 10 and the interposer structure 20. The third connection terminal 25 may connect the second board pad 14 with the interposer pad 27. Therefore, the circuit board 10 and the interposer structure 20 may be electrically connected to each other.

The third connection terminal 25 may be a solder bump that includes a low melting point metal, for example, tin (Sn) and a tin (Sn) alloy, but is not limited thereto. The third connection terminal 25 may have various shapes such as a land, a ball, a pin and a pillar. The third connection terminal 25 may be formed of a single layer or a multi-layer. When the third connection terminal 25 is formed of a single layer, the third connection terminal 25 may include, for example, a tin-silver (Sn—Ag) solder or copper (Cu). When the third connection terminal 25 is formed of a multi-layer, the third connection terminal 25 may include, for example, a copper (Cu) filler and a solder. The number, interval, arrangement, shape and the like of the third connection terminals 25 are not limited to the shown examples, and may vary depending on design.

In some embodiments, a first underfill 26 may be formed between the circuit board 10 and the interposer structure 20. The first underfill 26 may be in (e.g., may fill) a space between the circuit board 10 and the interposer structure 20. In addition, the first underfill 26 may be on (e.g., may cover) the third connection terminal 25. The first underfill 26 may prevent the interposer structure 20 from being broken by fixing the interposer structure 20 on the circuit board 10. The first underfill 26 may include, for example, an insulating polymer material such as an epoxy molding compound (EMC), but is not limited thereto.

In some embodiments, the first connection terminal 105 of the buffer die 100 may be connected to the interposer structure 20. In detail, the first connection terminal 105 may be electrically connected to the interposer redistribution layer 23. Therefore, the buffer die 100 and the interposer structure 20 may be electrically connected to each other. The first connection terminal 105 may electrically connect the circuit board 10 to the buffer die 100. For example, the circuit board 10 may be electrically connected to the buffer die 100 through the interposer structure 20 and the first connection terminal 105.

In some embodiments, a second underfill 103 may be formed between the interposer structure 20 and the buffer die 100. The second underfill 103 may be in (e.g., may fill) a space between the interposer structure 20 and the buffer die 100. In addition, the second underfill 103 may be on (e.g., may cover) the first connection terminal 105. The second underfill 103 may include, for example, an insulating polymer material such as an epoxy molding compound (EMC), but is not limited thereto.

The semiconductor package according to some embodiments may further include an adhesive layer 30 and a heat slug 40.

The adhesive layer 30 may be provided on the core die 200. The adhesive layer 30 may be in contact with an upper surface of the core die 200. The adhesive layer 30 may fix the mold layer ML, the core die 200 and the heat slug 40 by adhering them to one another. The adhesive layer 30 may include an adhesive material. For example, the adhesive layer 30 may include a curable polymer. The adhesive layer 30 may include, for example, an epoxy-based polymer.

The heat slug 40 may be disposed on the circuit board 10. The heat slug 40 may be on (e.g., may cover) the core die 200. The heat slug 40 may include a metallic material, but is not limited thereto.

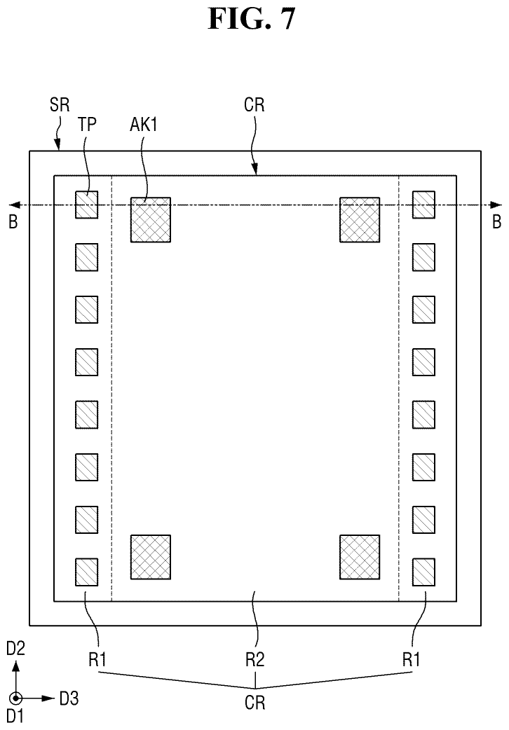

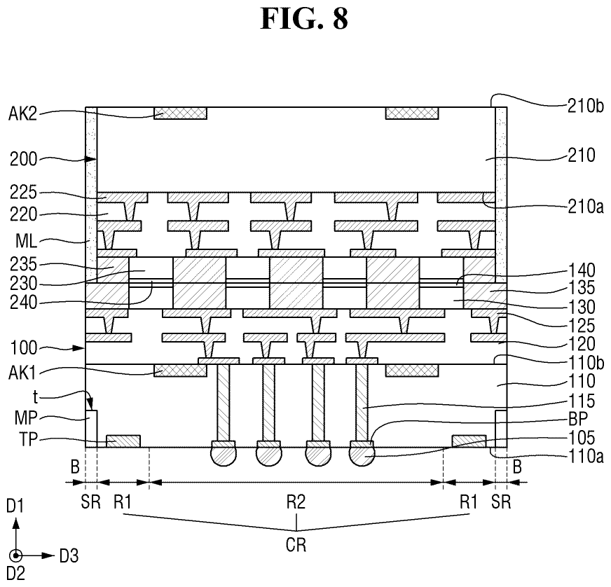

FIGS. 7 and 8 are example views illustrating a semiconductor package according to some other embodiments of the present disclosure. For reference, FIG. 8 is a cross-sectional view taken along line B-B of FIG. 7.

Referring to FIGS. 7 and 8, both a longitudinal side and a cross section of the first region R1 of the chip region CR may be in contact with the scribe lane region SR. That is, the second region R2 may not be disposed between the longitudinal side of the first region R1 and the scribe lane region SR. The second region R2 may be interposed only between a pair of sub-regions of the first region R1. For example, the longitudinal side of the first region R1 may extend in the second direction D2.

That is, the first alignment key AK1 disposed on the second region R2 may be interposed between the pair of sub-regions of the first region R1. In this case, the first alignment key AK1 may not completely overlap the test pad TP in the first direction D1. For example, the first alignment key AK1 and the test pad TP may not overlap each other in the first direction D1 or may only partially overlap each other in the first direction D1. For example, the first alignment key AK1 may be spaced apart from the test pad TP in the third direction D3.

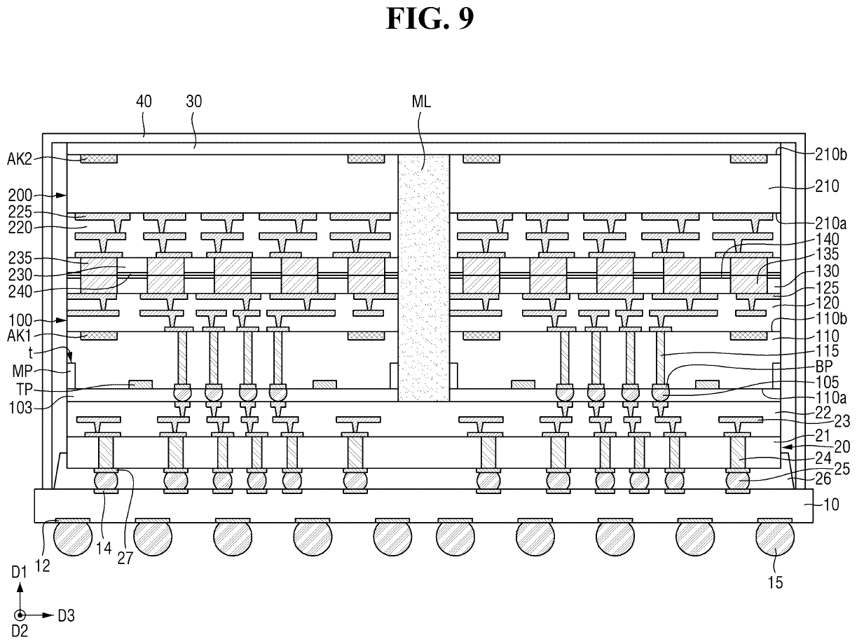

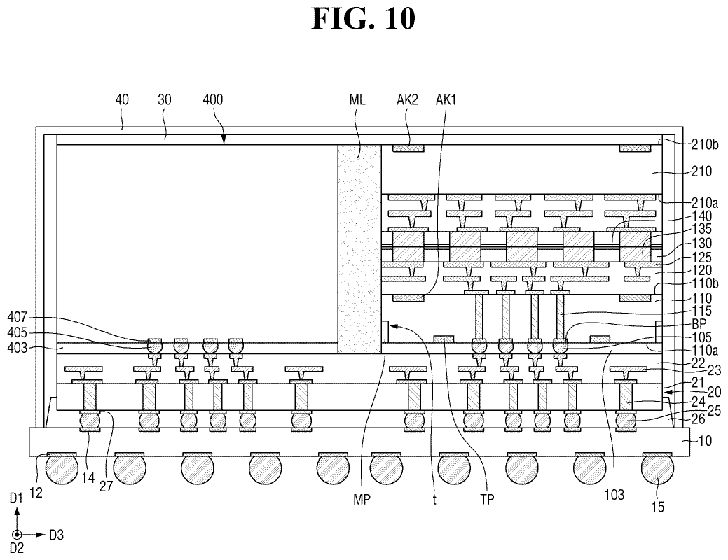

FIGS. 9 and 10 are example views illustrating a semiconductor package according to some other embodiments of the present disclosure.

First, referring to FIG. 9, the semiconductor package according to some embodiments may include a plurality of die structures. The die structures may be disposed on the same vertical level on the circuit board 10 in the first direction D1. For example, the die structures may be disposed to be spaced apart from each other in the third direction D3 on the circuit board 10.

In FIG. 9, each of the die structures may include one buffer die 100 and one core die 200, but the present disclosure is not limited thereto. In some embodiments, the die structure may include one buffer die 100 and two or more core dies 200. The mold layer ML may be interposed between the die structures. The mold layer ML may separate the die structures.

Referring to FIG. 10, the semiconductor package according to some embodiments may further include a semiconductor chip 400. The semiconductor chip 400 may be disposed on the circuit board 10. The semiconductor chip 400 may include integrated circuits. The integrated circuits may include a memory circuit, a logic circuit, or a combination thereof.

For example, the semiconductor chip 400 may be a logic semiconductor chip. For example, the semiconductor chip 400 may be an application processor (AP) such as a central processing unit (CPU), a graphic processing unit (GPU), a field-programmable gate array (FPGA), a digital signal processor (DSP), an encryption processor, a microprocessor, a microcontroller and an application-specific IC (ASIC), but is not limited thereto.

The semiconductor chip 400 may include chip pads 407 disposed therebelow. The interposer structure 20 and the semiconductor chip 400 may be electrically connected to each other through the chip pad 407.

Fourth connection terminals 405 may be disposed below the chip pads 407. The fourth connection terminal 405 may be interposed between the interposer structure 20 and the semiconductor chip 400. The fourth connection terminal 405 may electrically connect the interposer redistribution layer 23 to the chip pad 407 and may be between the interposer redistribution layer 23 and the chip pad 407.

The fourth connection terminal 405 may be a solder bump that includes a low melting point metal, for example, tin (Sn) and a tin (Sn) alloy, but is not limited thereto. The fourth connection terminal 405 may have various shapes such as a land, a ball, a pin and a pillar. The fourth connection terminal 405 may be formed of a single layer or a multi-layer. When the fourth connection terminal 405 is formed of a single layer, the fourth connection terminal 405 may include, for example, a tin-silver (Sn—Ag) solder or copper (Cu). When the fourth connection terminal 405 is formed of a multi-layer, the fourth connection terminal 405 may include, for example, a copper (Cu) filler and a solder. The number, interval, arrangement, shape and the like of the fourth connection terminals 405 are not limited to the shown examples, and may vary depending on design.

In some embodiments, a third underfill 403 may be formed between the semiconductor chip 400 and the interposer structure 20. The third underfill 403 may be in (e.g., may fill) a space between the interposer structure 20 and the semiconductor chip 400. In addition, the third underfill 403 may be on (e.g., may cover) the fourth connection terminal 405. The third underfill 403 may include, for example, an insulating polymer material such as an epoxy molding compound (EMC), but is not limited thereto.

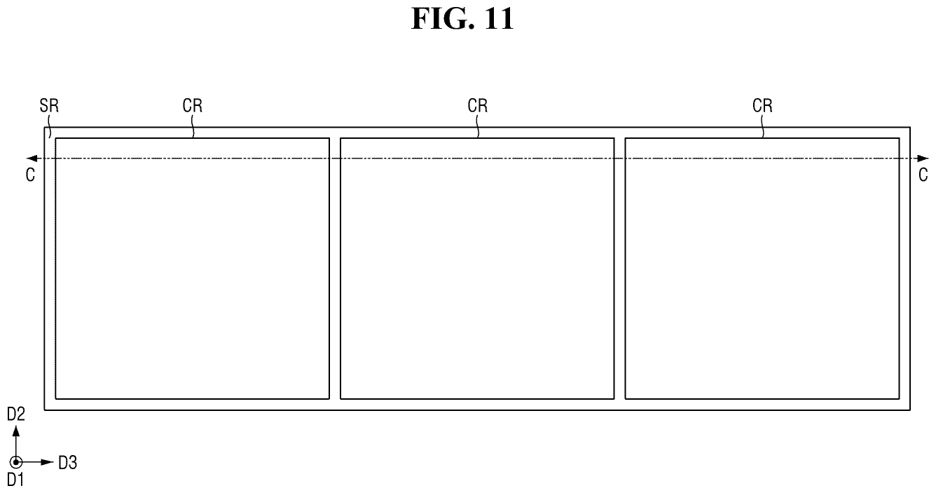

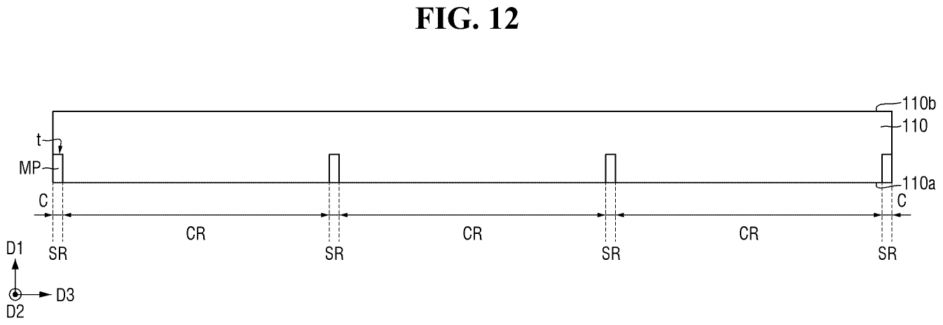

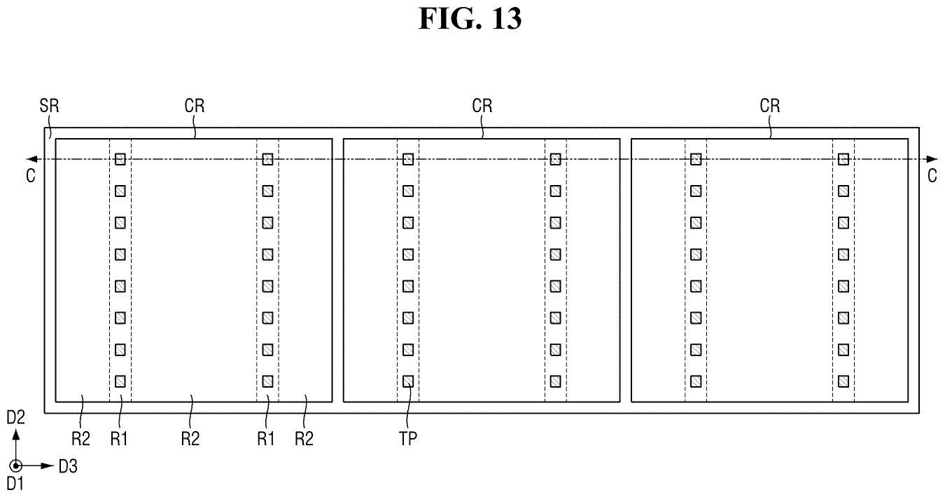

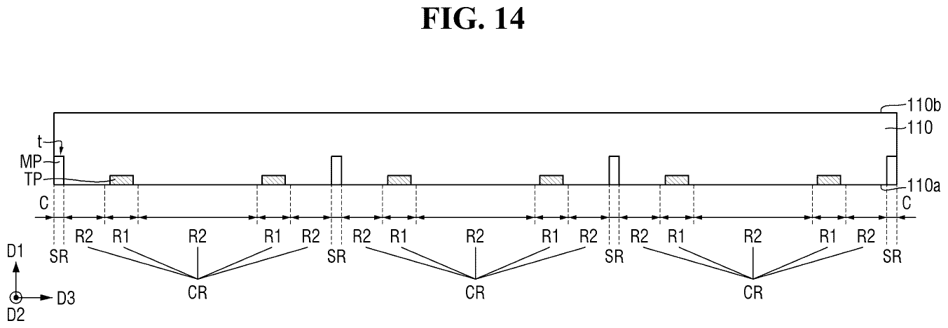

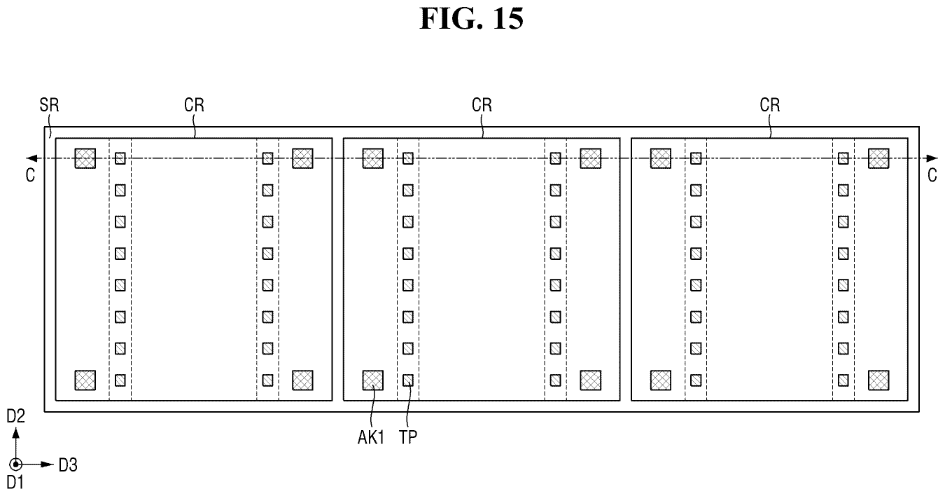

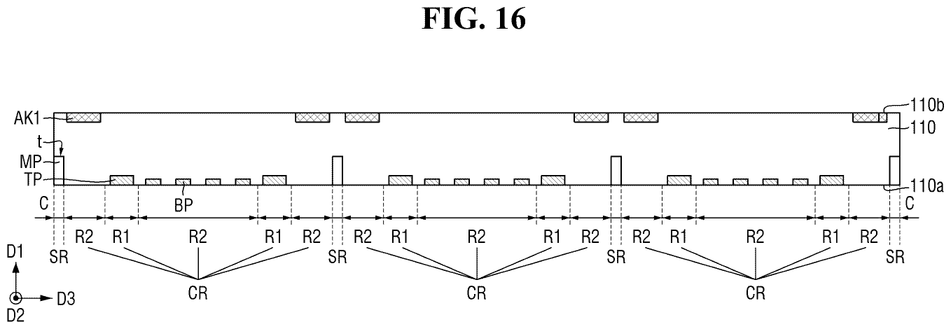

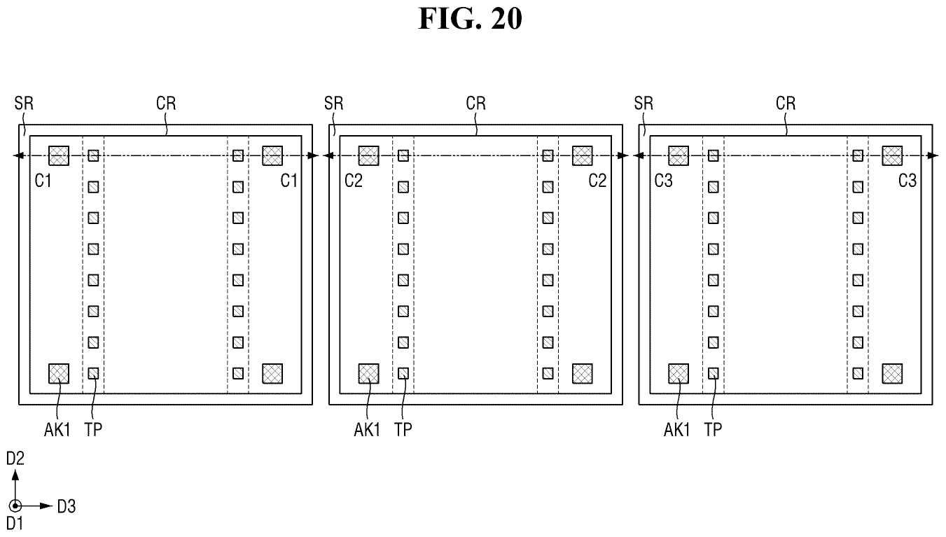

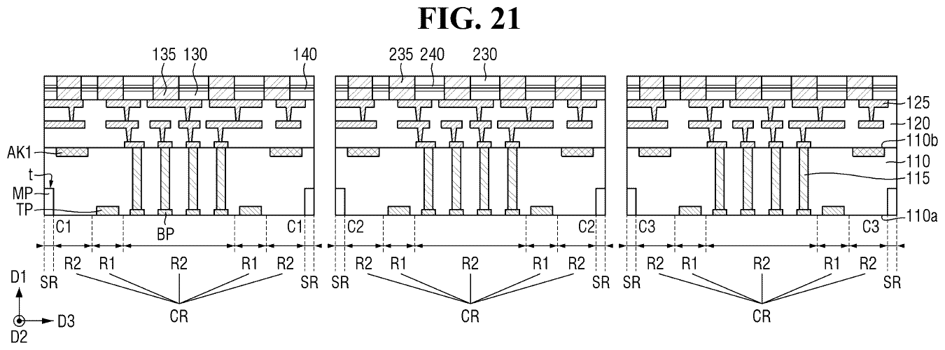

Hereinafter, a method of manufacturing a semiconductor package according to some embodiments of the present disclosure will be described with reference to FIGS. 11 to 21. FIGS. 11 to 21 are intermediate views illustrating a method of manufacturing a semiconductor package according to some embodiments of the present disclosure. For reference, FIG. 12 is a cross-sectional view taken along line C-C of FIG. 11. FIG. 14 is a cross-sectional view taken along line C-C of FIG. 13. FIGS. 16 to 19 are cross-sectional views taken along line C-C of FIG. 15. FIG. 21 is a cross-sectional view taken along lines C1-C1, C2-C2 and C3-C3 of FIG. 20.

Referring to FIGS. 11 and 12, a first substrate 110 may be provided. The first substrate 110 may include a first surface 110a and a second surface 110b, which are opposite to each other in the first direction D1.

The first substrate 110 may include a scribe lane region SR and a chip region CR. The scribe lane region SR may define the chip region CR. Although FIG. 11 shows that the scribe lane region SR defines three chip regions CR, the present disclosure is not limited thereto. In some embodiments, the scribe lane region SR may define four or more chip regions CR

A trench ‘t’ may be formed in the first substrate 110. The trench ‘t’ may extend from the first surface 110a toward the second surface 110b. The trench ‘t’ may not pass through the entire first substrate 110. A metal pattern MP may be formed in the trench ‘t’. The scribe lane region SR may be defined by the metal pattern MP.

Referring to FIGS. 13 and 14, test pads TP may be formed in the first substrate 110. The test pad TP may expose the first surface 110a of the first substrate 110. For example, a lower surface of the test pad TP may be coplanar with the first surface 110a. A plurality of test pads TP may be arranged longitudinally in the second direction D2.

The chip region CR may include a first region R1 and a second region R2. A region in which the plurality of test pads TP are disposed may be the first region R1, and a region other than the first region R1 may be the second region R2. Since the plurality of test pads TP are arranged longitudinally in the second direction D2, the first region R1 may also extend longitudinally in the second direction D2.

Referring to FIGS. 15 and 16, bump pads BP and first alignment keys AK1 may be formed in the first substrate 110. Each of the bump pad BP and the first alignment key AK1 may be formed in the chip region CR. For example, each of the bump pad BP and the first alignment key AK1 may be formed in the second region R2. Each of the bump pad BP and the first alignment key AK1 may not overlap the test pad TP in the first direction D1. For example, each of the bump pad BP and the first alignment key AK1 may be spaced apart from the test pad TP in the third direction D3.

The bump pad BP may expose the first surface 110a of the first substrate 110. For example, a lower surface of the bump pad BP may be coplanar with the first surface 110a. The bump pad BP may be interposed between a pair of sub-regions of the first region R1. That is, the bump pad BP may be disposed between ones of the test pads TP, which are spaced apart from each other in the third direction D3.

The first alignment key AK1 may expose the second surface 110b of the first substrate 110. For example, an upper surface of the first alignment key AK1 may be coplanar with the second surface 110b. The first alignment key AK1 may be interposed between the test pad TP and the scribe lane region SR.

Although FIGS. 13 to 16 show that the test pad TP and the bump pad BP are formed through their respective processes different from each other, the present disclosure is not limited thereto. In some embodiments, the test pad TP and the bump pad BP may be formed through the same process.

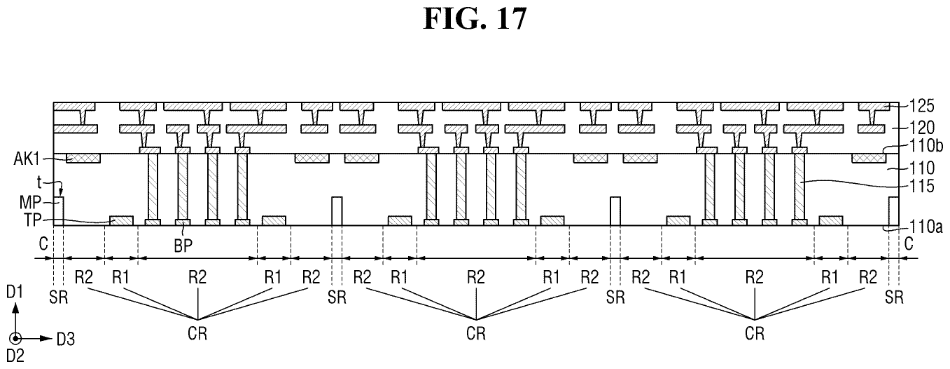

Referring to FIG. 17, first through vias 115 may be formed in the first substrate 110. The first through via 115 may be connected to the bump pad BP by passing through the first substrate 110.

Subsequently, a first insulating layer 120 and a first redistribution layer 125 may be formed on the second surface 110b of the first substrate 110. The first redistribution layer 125 may be formed in the first insulating layer 120. The first redistribution layer 125 disposed at the lowest level in the first direction D1 is connected to the first through via 115. The first redistribution layer 125 disposed at the highest level in the first direction D1 exposes an upper surface of the first insulating layer 120. For example, the first redistribution layer 125 at the highest level in the first direction D1 may be coplanar with the upper surface of the first insulating layer 120.

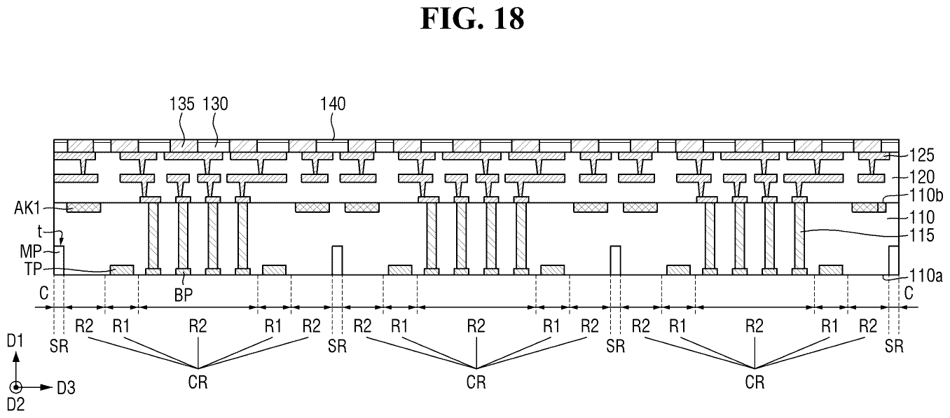

Referring to FIG. 18, a first passivation layer 130 may be formed on the first insulating layer 120 and the first redistribution layer 125. The first passivation layer 130 may extend longitudinally along the upper surfaces of the first insulating layer 120 and the first redistribution layer 125. Subsequently, a first bonding insulating film 140 may be formed. The first bonding insulating film 140 may be on (e.g., may cover) an upper surface of the first passivation layer 130.

Subsequently, the first bonding pads 135 may be formed. The first bonding pad 135 may pass through the first bonding insulating film 140 and the first passivation layer 130. The first bonding pad 135 may be connected to the first redistribution layer 125 by passing through the first bonding insulating film 140 and the first passivation layer 130.

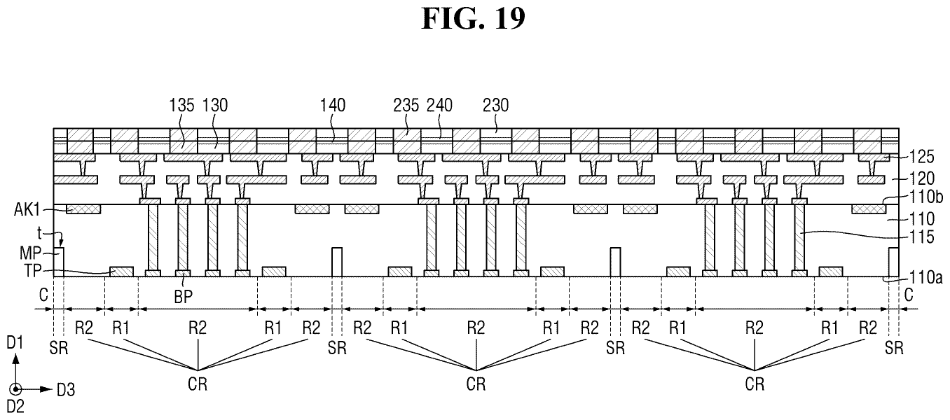

Referring to FIG. 19, a second passivation layer 230, a second bonding insulating film 240 and second bonding pads 235 may be formed on the first passivation layer 130 and the first bonding pads 135. The second bonding insulating film 240 may be bonded to the first bonding insulating film 140, and the second bonding pad 235 may be bonded to the first bonding pad 135.

Referring to FIGS. 20 and 21, the first substrate 110 may be cut based on the scribe lane region SR. A plurality of buffer dies may be formed by cutting the first substrate 110.

Subsequently, referring back to FIG. 2, a second redistribution layer 225 and a second substrate 210 may be formed on the second bonding pad 235.

Although FIGS. 19 to 21 show that the first substrate 110 is cut after the second bonding pad 235 is formed, the present disclosure is not limited thereto. In some embodiments, after the second bonding pad 235 is formed and then the second substrate 210 is formed on the second bonding pad 235, the first substrate 110 and the second substrate 210 may be cut at the same time. Also, in some other embodiments, the first substrate 110 may be cut after the first bonding pad 135 is formed. In this case, after the first substrate 110 is cut, the core die 200 may be formed on the first bonding pad 135.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

Although example embodiments of the present disclosure have been described with reference to the accompanying drawings, the present disclosure is not limited to the above embodiments and may be executed in various different forms. Thus, a person with ordinary skill in the art will understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor package comprising:
a buffer die; and
a core die on the buffer die,
wherein the buffer die comprises:
a first substrate including a scribe lane region and a chip region defined by the scribe lane region, the first substrate having first and second surfaces opposite to each other in a first direction;
a bump pad in the first substrate and including a lower surface that is coplanar with the first surface of the first substrate;
a test pad in the first substrate and including a lower surface that is coplanar with the first surface of the first substrate; and
a first alignment key in the first substrate and including an upper surface that is coplanar with the second surface of the first substrate,
wherein the core die comprises:
a second substrate on the second surface of the first substrate, the second substrate including a third surface facing the second surface of the first substrate and a fourth surface opposite to the third surface; and
a second alignment key in the second substrate and including an upper surface that is coplanar with the fourth surface of the second substrate,
wherein the chip region includes a first region having the test pad therein and a second region other than the first region, and
wherein the first alignment key is in the second region.

2. The semiconductor package of claim 1, wherein the first region of the chip region includes a pair of sub-regions extending in a second direction and spaced apart from each other in a third direction, and
wherein each of the second direction and the third direction intersects the first direction.

3. The semiconductor package of claim 2, wherein the first alignment key is between the pair of sub-regions.

4. The semiconductor package of claim 2, wherein the first alignment key is not between ones of the pair of sub-regions, and the first alignment key is between a first one of the pair of sub-regions and the scribe lane region.

5. The semiconductor package of claim 1, wherein a size of the bump pad is less than that of the test pad.

6. The semiconductor package of claim 1, wherein the buffer die further comprises a first bonding pad on the second surface of the first substrate,
wherein the core die further comprises a second bonding pad on the third surface of the second substrate, and
wherein the first bonding pad and the second bonding pad are in contact with each other.

7. The semiconductor package of claim 6, wherein the first bonding pad and the second bonding pad are electrically connected to each other such that the buffer die is electrically connected to the core die.

8. The semiconductor package of claim 1, wherein the first and second alignment keys are aligned with each other in the first direction.

9. The semiconductor package of claim 1, wherein the first alignment key does not overlap the test pad in the first direction.

10. The semiconductor package of claim 1, wherein the first substrate includes a trench that extends from the first surface of the first substrate toward the second surface of the first substrate on the scribe lane region, and
wherein a metal material is in the trench.

11. The semiconductor package of claim 1, wherein the test pad is configured to receive an electrical signal in an electrical die sorting (EDS) process.

12. The semiconductor package of claim 1, further comprising a circuit board on the first surface of the first substrate below the buffer die, and a connection terminal that electrically connects the circuit board to the buffer die,
wherein the connection terminal is electrically connected to the bump pad.

13. A semiconductor package comprising:
a buffer die; and
first and second core dies stacked in a first direction on the buffer die,
wherein the buffer die comprises:
a first substrate including first and second surfaces opposite to each other in the first direction;
a plurality of bump pads in the first substrate, including respective lower surfaces that are coplanar with the first surface of the first substrate, and configured to electrically connect to an external device;
a plurality of test pads in the first substrate, including respective lower surfaces that are coplanar with the first surface of the first substrate, and configured to receive an electrical signal in an electrical die sorting (EDS) process;
a first bonding pad on the second surface of the first substrate; and
a first alignment key in the first substrate and including an upper surface that is coplanar with the second surface of the first substrate,
wherein the first core die comprises:
a second substrate on the second surface of the first substrate, the second substrate including a third surface facing the second surface of the first substrate and a fourth surface opposite to the third surface;
a second alignment key in the second substrate and including an upper surface that is coplanar with the fourth surface of the second substrate;
a second bonding pad between the third surface of the second substrate and the second surface of the first substrate; and
a third bonding pad on the fourth surface of the second substrate,
wherein the second core die comprises:
a third substrate on the fourth surface of the second substrate, the third substrate including a fifth surface facing the fourth surface of the second substrate and a sixth surface opposite to the fifth surface;
a third alignment key in the third substrate and including an upper surface that is coplanar with the sixth surface of the third substrate; and
a fourth bonding pad between the fourth surface of the second substrate and the fifth surface of the third substrate,
wherein the first bonding pad and the second bonding pad are in contact with each other and electrically connect the buffer die to the first core die,
wherein the third bonding pad and the fourth bonding pad are in contact with each other and electrically connect the first core die to the second core die, and
wherein the first alignment key does not overlap the plurality of test pads in the first direction.

14. The semiconductor package of claim 13, wherein the buffer die further comprises first redistribution patterns between the first bonding pad and the first substrate, and at least a portion of the first redistribution patterns overlaps the first alignment key in the first direction.

15. The semiconductor package of claim 13, wherein the plurality of test pads are arranged in series in a second direction intersecting the first direction.

16. The semiconductor package of claim 13, wherein the first alignment key, the second alignment key and the third alignment key are aligned with one another in the first direction.

17. The semiconductor package of claim 13, further comprising a mold layer on sidewalls of the first and second core dies,
wherein the first alignment key does not overlap the mold layer in the first direction.

18. A semiconductor package comprising:
a circuit board;
an interposer structure on the circuit board;
a die structure on the interposer structure and electrically connected to the interposer structure; and
a connection terminal between the die structure and the interposer structure,
wherein the die structure includes a buffer die and a core die on the buffer die,
wherein the buffer die comprises:
a first substrate including a scribe lane region and a chip region defined by the scribe lane region, the first substrate having first and second surfaces opposite to each other in a first direction;
a bump pad in the first substrate, including a lower surface that is coplanar with the first surface of the first substrate, and electrically connected to the connection terminal;
a test pad in the first substrate, including a lower surface that is coplanar with the first surface of the first substrate, and configured to receive an electrical signal in an electrical die sorting (EDS) process;
a first bonding pad on the second surface of the first substrate; and
a first alignment key in the first substrate and including an upper surface that is coplanar with the second surface of the first substrate,
wherein the core die comprises:
a second substrate on the second surface of the first substrate, the second substrate including a third surface facing the second surface of the first substrate and a fourth surface opposite to the third surface;
a second bonding pad between the third surface of the second substrate and the second surface of the first substrate; and
a second alignment key in the second substrate, including an upper surface that is coplanar with the fourth surface of the second substrate, and aligned with the first alignment key in the first direction,
wherein the first bonding pad and the second bonding pad are in contact with each other and electrically connect the buffer die to the core die,
wherein the chip region includes a first region having the test pad therein and a second region other than the first region, and
wherein the first alignment key is in the second region.

19. The semiconductor package of claim 18, wherein a size of the bump pad is less than that of the test pad.

20. The semiconductor package of claim 18, wherein the first substrate includes a trench that extends from the first surface of the first substrate toward the second surface of the first substrate on the scribe lane region, and
wherein a metal material is in the trench.
